(19) United States
(12) Patent Application Publication
(10) Pub. No.: US 2007/0153609 A1
(43) Pub. Date: Jul. 5, 2007

(54) One-time programmable memory and method of burning data of the same

(75) Inventors: Xiao Long Wu, Taipei (TW); Yi Chou Hung, Taipei (TW)

Correspondence Address: HDSL, 4331 STEVENS BATTLE LANE, FAIRFAX, VA, 22033, US

(73) Assignee: Fortune Semiconductor Corporation

(21) Appl. No.: 11/325,541

(22) Filed: Jan. 5, 2006

(51) Int. Cl. G11C 17/18

(52) U.S. Cl. 365/225.7

(57) ABSTRACT

A one-time programmable memory includes a digital interface, a fuse control circuit, a fuse data register, and a programmable fuse array. The digital interface is provided for receiving a fuse data sent from a client, and the fuse control circuit outputs a programmable signal according to the fuse data. The fuse data register is provided for receiving and buffering the fuse data, and the programmable fuse array includes a plurality of programmable data fuses, and the programmable fuse array is provided or receiving and blowing the programmable data fuse according to the programmable signal and fuse data.

### BACKGROUND OF THE INVENTION

1. Field of the Invention

The present invention relates to a one-time programmable memory, and more particularly to the structure of a one-time programmable memory and the method of burning data into the one-time programmable memory.

2. Description of Prior Art

In general, a programmable fuse array can be used for connecting an electronic circuit that requires an adjustment. Such fuse array circuit provides a logic high potential and a logic low potential depending on whether or not a fuse is blown. The fuse in the array is blown selectively to provide a digit bit. For example, a digital bit is given to a digital-to-analog converter (DAC) for providing a desired adjusting voltage, such as an operational amplifier can be designed, so that its drift voltage can be adjusted.

The fuse in the programmable fuse array can be programmed once only, and thus a blown fuse cannot be blown again. In common practices, such programmable fuse array can be fabricated in an integrated circuit for measuring or controlling an electronic device.

Referring to FIG. 3 for the circuit block diagram of a one-time programmable fuse array circuit as disclosed in U.S. Pat. No. 6,690,193, a one-time programmable fuse array circuit 40 according to such prior art provides a digital signal to a programmable analog component. An integrated circuit sends a digital bit pattern from a digital interface 42 to a fuse array circuit 40. Initially, an output 44 of the fuse array circuit 40 provides a user-specified bit pattern to the programmable analog component, and users can change the bit pattern as needed.

The fuse array circuit 40 also includes a programmable circuit 46 and at least N pieces of programmable data fuse arrays 48. Each programmable data fuse can be changed from a complete state to a blown state according to the programmable signal received by the programmable circuit 46. The programmable circuit 46 receives a user-specified digital bit pattern. To make sure that the data fuse has been programmed correctly, an acknowledge means 52 is adopted to produce an output signal to instruct and match the data fuse state of a specified pattern. The programmable circuit 46 receives an output signal of the acknowledge means 52. If the acknowledge means 52 indicates that the data fuse matches the specified pattern, the lock fuse will be blown.

The user-specified pattern and data fuse state are transmitted to the programmable analog component through a multiplex 56 by multiplexing. Initially, the specified pattern is sent to the programmable analog component, and the pattern change will be changed if necessary to achieve the required result for the programmable analog component. If the required result is achieved, then the data fuse will be blown, and the state of the data fuse will be sent to the programmable analog component to provide a permanent control signal (trim).

In the aforementioned prior art, several registers are used to test and burn data, so that the burning method of the one-time programmable memory becomes relatively troublesome, and the entire circuit design also becomes relatively complicated.

### SUMMARY OF THE INVENTION

The present invention is to overcome the shortcomings of the prior art and avoid the existing deficiencies by providing a one-time programmable memory, such that after a chip is fabricated, a data is recorded into the chip by a procedure, so as to omit the steps of modifying the circuit and fabricating the chip again, as well as simplifying the circuit design and saving the cost for the one-time programmable memory.

The present invention provides a one-time programmable memory that comprises a digital interface, a fuse control circuit, a fuse data register, and a programmable fuse array. The digital interface is provided for receiving a fuse data transmitted from a client. The fuse control circuit outputs a programmable signal according to the fuse data. The fuse data register is provided for receiving and buffering the fuse data. The programmable fuse array includes a plurality of programmable data fuses, and the programmable fuse array is provided for receiving and blowing the programmable data fuses according to the programmable signal and the fuse data.

The present invention provides a method of burning data for a one-time programmable memory, comprising the steps of:

receiving a fuse data;

buffering the fuse data;

outputting a programmable signal according to the fuse data; and

receiving the programmable signal and burning the programmable fuse array according to the programmable signal and the fuse data.

### BRIEF DESCRIPTION OF DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is a schematic circuit diagram of a one-time programmable memory of the invention;

FIG. 2 is schematic circuit diagram of switching between a signal pad and a VDDF pad according to the present invention; and

FIG. 3 is a circuit block diagram of a prior art one-time programmable fuse array circuit.

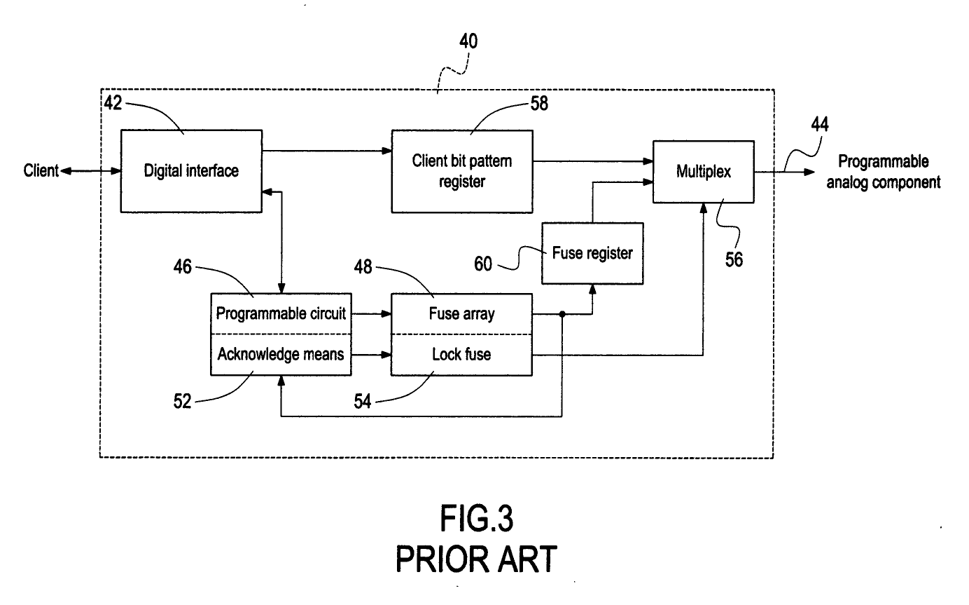

### DETAILED DESCRIPTION OF THE INVENTION

The technical characteristics, features and advantages of the present invention will become apparent in the following detailed description of the preferred embodiments with reference to the accompanying drawings.

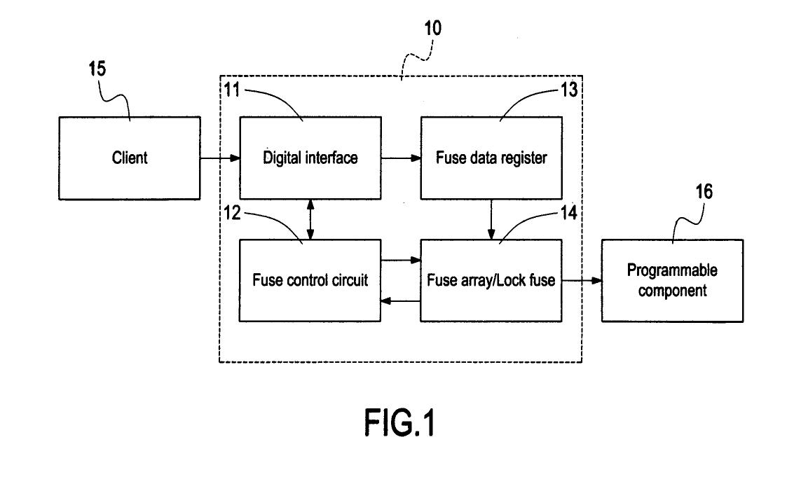

Referring to FIG. 1 for the circuit block diagram of a one-time programmable memory in accordance with the present invention, wherein the one-time programmable memory 10 comprises: a digital interface 11, a fuse control circuit 12, a fuse data register 13, and a programmable fuse array 14, and the one-time programmable memory 10 is electrically coupled to a client 15 and a programmable component 16.

In this preferred embodiment, the digital interface 11 is electrically coupled to the client 15 and receives a fuse data transmitted from the client 15. For those skilled in the arts, it is easily known that the digital interface 11 could use the I²C communication protocol.

The fuse control circuit 12 is electrically coupled to the digital interface 11 and outputs a programmable signal to the programmable fuse array 14 according to the fuse data.

The fuse data register 13 is electrically coupled to the digital interface 11 and the programmable fuse array 14, and the fuse data register 13 is provided for receiving and buffering the fuse data.

The programmable fuse array 14 includes a plurality of programmable data fuses, and this programmable fuse array 14 is provided for receiving and blowing the programmable data fuse according to the programmable signal and the fuse data. Each programmable data fuse is changed from a complete state to a blown state according to an individual programmable signal.

In this preferred embodiment, the programmable fuse array 14 will output an acknowledge result to the programmable component 16, if a fuse is in a blown mode.

In this preferred embodiment, the client 15 will enter the one-time programmable memory 10 into a blown mode before operating the one-time programmable memory 10 as a programmable memory, and then the client 15 will output the desired fuse data to the digital interface 11 for blowing the fuse and will store the digital interface 11 in the fuse data register 13.

Then, the fuse control circuit 12 checks the state of a lock fuse in the programmable fuse array 14. If the lock fuse is detected as in an ON state, then the one-time programmable memory 10 will allow data to be written, and then the fuse data buffered in the fuse data register 13 will be burned into the programmable fuse array 14. On the other hand, if the lock fuse is detected as in an OFF state, then the one-time programmable memory 10 will not allow any data to be written.

The lock fuse is a fuse bit in the programmable fuse array 14. The data burned into the programmable fuse array 14 is an input of the programmable component 16. If all memories are programmed, the lock fuse will be burned into the client 15 to indicate that the one-time programmable memory 10 can no longer be burned again.

In a preferred embodiment of the present invention, the programmable component 16 includes but not limited to an analog programmable component or a digital programmable component.

In a preferred embodiment of the present invention, the client 15 further includes outputting a read signal to the digital interface 11. The digital interface 11 receives and outputs the read signal, so that the fuse control circuit 12 can output the fuse data in the programmable fuse array.

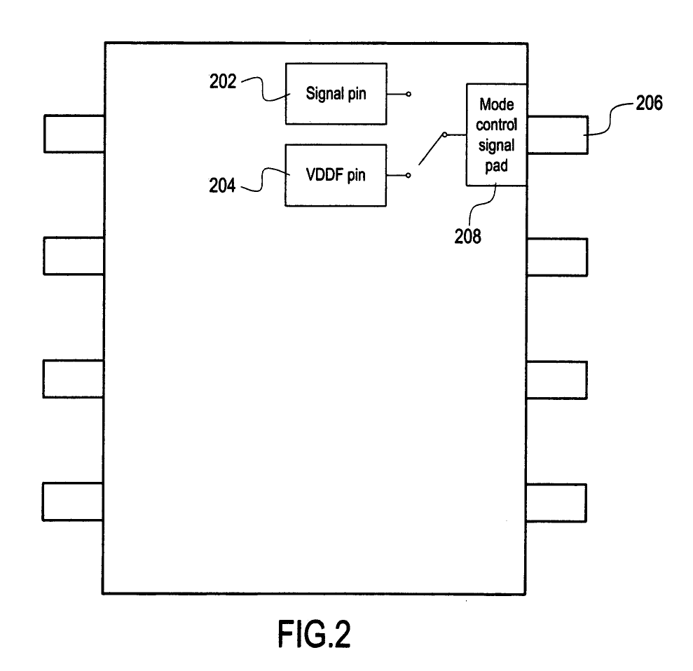

Refer to FIG. 2 for the schematic circuit diagram of switching between a signal pad and a VDDF pad according to the present invention. In this preferred embodiment, the lock fuse bit can be used for controlling the switch of the solder pad such as the signal pin 202 and the VDDF (fuse repair voltage source) pin 204. In a blown mode, the chip pin 206 is coupled to the VDDP PIN 204 through the mode control signal pad 208. In other words, if the one-time programmable memory 10 can no longer be burned, the chip pin 206 will be coupled to the signal pin 202 (depending on the designer's design) through the mode control signal pad 208 for the use in a general mode or an acknowledge mode.

Such switch allows the client 15 to program a packaged chip easily. Furthermore, it is not necessary to design an additional chip pin 206 for the VDDP PIN 204.

In summation to the description above, data can be recorded in the one-time programmable memory of the present invention by a procedure, after the chip is produced. The invention can omit the steps of modifying the circuit and producing the chip again, so as to simplify the circuit and save the cost of the one-time programmable memory.

The present invention are illustrated with reference to the preferred embodiment and not intended to limit the patent scope of the present invention. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A one-time programmable memory, applicable for programming a programmable component, and the one-time programmable memory being electrically coupled to a client and the programmable component, and the one-time programmable memory comprising:
a digital interface, electrically coupled to the client for receiving a fuse data transmitted from the client;
a fuse control circuit, electrically coupled to the digital interface for outputting a programmable signal according to the fuse data;
a fuse data register, electrically coupled to the digital interface for receiving and buffering the fuse data; and
a programmable fuse array, having a plurality of programmable data fuses, and the programmable fuse array being electrically coupled to the fuse data register and the fuse control circuit for receiving and blowing the programmable data fuses according to the programmable signal and the fuse data.

2. The one-time programmable memory of claim 1, wherein each programmable data fuse is converted to a complete state into a blown state according to each of the programmable signals.

3. The one-time programmable memory of claim 1, wherein the digital interface receives and outputs the read signal and drives the fuse control circuit to output the fuse data in the programmable fuse array.

4. The one-time programmable memory of claim 1, wherein the programmable fuse array will output an acknowledge result to the programmable component, if a fuse is in a blown mode.

5. The one-time programmable memory of claim 1, wherein the programmable fuse array includes a lock fuse, and the fuse control circuit checks the lock fuse to confirm whether or not to carry out a burning process for the programmable fuse array.

6. The one-time programmable memory of claim 5, wherein the lock fuse controls a signal pin, such that if the lock fuse is not blown, then the signal pin will be connected to a voltage source, and if the lock fuse is blown, then the signal pin will be connected to a signal input terminal.

7. The one-time programmable memory of claim 4, wherein the programmable component is an analog programmable component.

8. The one-time programmable memory of claim 4, wherein the programmable component is a digital programmable component.

9. A method of burning data for a one-time programmable memory, and the one-time programmable memory including a programmable fuse array, and the programmable fuse array including a lock fuse, and the method of burning data comprising the steps of:
receiving a fuse data;
buffering the fuse data;
outputting a programmable signal according to the fuse data; and
receiving the programmable signal and burning the programmable fuse array according to the programmable signal and the fuse data.

10. The method of burning data for a one-time programmable memory of claim 9, wherein the fuse data is buffered in the fuse data register.

11. The method of burning data for a one-time programmable memory of claim 9, wherein the state of the lock fuse is checked before the programmable data fuse is blown.

12. The method of burning data for a one-time programmable memory of claim 11, wherein the lock fuse has a bit burned therein to indicate that the one-time programmable memory can no longer be burned, after the process of programming the one-time programmable memory is completed.

13. The method of burning data for a one-time programmable memory of claim 11, wherein the programming fuse array stops burning, if the lock fuse in an off state is detected.

14. A burning circuit for burning a programmable fuse array, comprising:
a digital interface, electrically coupled to a client for receiving a fuse data transmitted from the client;
a fuse control circuit, electrically coupled to the digital interface for outputting a programmable signal according to the fuse data; and
a fuse data register, electrically coupled to the digital interface for receiving and buffering the fuse data;
wherein, the fuse control circuit checks whether or not the programmable fuse array is burned, and if not, then the fuse control circuit burns a data from the fuse data register to the programmable fuse array.

15. The burning circuit for burning a programmable fuse array of claim 14, wherein the programmable fuse array will output an acknowledge result to the programmable component, if a fuse is in a blown mode.

16. The burning circuit for burning a programmable fuse array of claim 14, wherein the programmable fuse array includes a lock fuse, and the fuse control circuit checks the lock fuse to confirm whether or not the programmable fuse array can be burned.

17. The burning circuit for burning a programmable fuse array of claim 16, wherein the lock fuse controls a signal pin, and if the lock fuse is not blown, then the signal pin is coupled to a voltage source, and if the lock fuse is blown, then the signal pin is coupled to a signal input terminal.

18. The burning circuit for burning a programmable fuse array of claim 15, wherein the programmable component is an analog programmable component.

19. The burning circuit for burning a programmable fuse array of claim 15, wherein the programmable component is a digital programmable component.
